(19) United States
(12) Patent Application Publication
(10) Pub. No.: US 2019/0190440 A1
(43) Pub. Date: Jun. 20, 2019

(54) SYSTEMS AND METHODS FOR IMPROVING LIGHT COLLECTION OF PHOTOVOLTAIC PANELS

(71) Applicant: Alion Energy, Inc., Richmond, CA (US)

(72) Inventors: Mark Kingsley, Hollis, NH (US); Søren Jensen, Corte Madera, CA (US); Nicholas A. Barton, Richmond, CA (US); Craig B. E. Wildman, Kensington, CA (US)

(21) Appl. No.: 16/201,896

(22) Filed: Nov. 27, 2018

Related U.S. Application Data
(60) Provisional application No. 62/591,644, filed on Nov. 28, 2017.
(60) Provisional application No. 62/616,996, filed on Jan. 12, 2018.
(60) Provisional application No. 62/722,733, filed on Aug. 24, 2018.

(51) Int. Cl. H02S 20/32; H01L 31/068

(52) U.S. Cl. CPC H02S 20/32; H01L 31/0684

(57) ABSTRACT

Systems and methods for structures that support bifacial photovoltaic panels are presented. A system comprising a support structure mounted to an underside of bifacial photovoltaic panels arranged in a row is provided herein. The support structure comprises one or more elongated structural members extending along and in a direction parallel to the row. The support structure further comprises one or more pivot arms that rotate about an axle at a top of the support structure. The one or more pivot arms are positioned in a perpendicular direction to the one or more elongated structural members. The one or more pivot arms connected to the one or more elongated structural members. The one or more structural elements of the support structure have a reflective outer surface to increase reflected light to the underside of the bifacial photovoltaic panels.

### CROSS-REFERENCE TO RELATED APPLICATIONS

This application claims priority to U.S. Provisional Application No. 62/591,644, filed Nov. 28, 2017, to U.S. Provisional Application No. 62/616,996, filed Jan. 12, 2018, and to U.S. Provisional Application No. 62/722,733, filed Aug. 24, 2018, the entirety of each of which are herein incorporated by reference.

### FIELD

The current subject matter pertains to solar photovoltaic (PV) power plants.

### BACKGROUND

PV panels have a front side and a back side. Some PV panels, known as bifacial panels, can collect light from both the front side and the back side. The light incident on the back side of the PV panel can be limited since the back side of the panel may be pointed away from the sun. Power generation of a bifacial PV can be improved by increasing incident light on the backside of the panels.

### SUMMARY

A system comprising a support structure mounted to an underside of bifacial photovoltaic panels arranged in a row is provided herein. The support structure comprises one or more elongated structural members extending along and in a direction parallel to the row. The support structure further comprises one or more pivot arms that rotate about an axle at a top of the support structure, the one or more pivot arms positioned in a perpendicular direction to the one or more elongated structural members, the one or more pivot arms connected to the one or more elongated structural members. The one or more structural elements of the support structure have a reflective outer surface to increase reflected light to the underside of the bifacial photovoltaic panels.

A method is provided herein for assembling a system for rotating bifacial photovoltaic panels arranged in a row. In the method, a support structure is assembled for the bifacial photovoltaic panels. One or more pivot arms that rotate about an axle at a top of the support structure are positioned. One or more elongated structural members are positioned to extend along and parallel to the row and in a perpendicular direction to the one or more pivot arms. The one or more elongated structural members are connected to the one or more pivot arms. An underside of the bifacial photovoltaic panels is mounted to the support structure. One or more structural elements of the support structure are coated with a reflective coating to increase reflected light to the underside of the bifacial photovoltaic panels.

A system comprising a support structure and one or more bifacial photovoltaic panels arranged in a row is provided herein. The support structure comprises one or more elongated structural members extending along and parallel to the row. The support structure further comprises one or more pivot arms that rotate about an axle at a top of the support structure positioned in a perpendicular direction to the one or more elongated structural members. The one or more pivot arms are connected to the one or more elongated structural members. One or more bifacial photovoltaic panels are arranged in a row. The one or more bifacial photovoltaic panels are affixed to the support structure. The one or more elongated structural members have an outer surface with a reflective coating to increase reflected light to the surface of the one or more bifacial photovoltaic panels.

### BRIEF DESCRIPTION OF THE FIGURES

FIGS. 1A and 1B show two perspective views of a solar tracker with a number of solar panels mounted on it.

FIG. 2 schematically illustrates a detailed view of back sides of solar panels and a mounting structure from a solar collector.

FIG. 3 schematically illustrates a close-up view of a clamp standoff.

FIG. 4 schematically illustrates a clamp standoff in detail.

FIG. 5 schematically illustrates a perspective view of a maintenance vehicle that can travel along a row of solar collectors and conduct maintenance processes as it goes.

FIG. 6 shows a perspective view of a maintenance vehicle performing a maintenance task on a solar collector.

FIGS. 7A and 7B show perspective views of a maintenance vehicle performing a maintenance task on a solar collector, according to some embodiments.

FIG. 8 schematically illustrates another embodiment of a maintenance vehicle that can perform maintenance on a solar collector.

FIG. 9 schematically illustrates an alternative embodiment of a solar collector, where this solar collector is being serviced by a cleaning machine.

FIG. 10 shows a perspective view of a tracking solar collector.

FIG. 11 shows a second perspective view of a tracking solar collector.

FIG. 12 shows a third perspective view of a tracking solar collector.

FIG. 13 depicts a method for assembling the solar collectors shown in FIGS. 10, 11, and 12, according to one embodiment.

### DETAILED DESCRIPTION

The current subject matter is directed to a solar tracker structure and related maintenance practices that enable bifacial panels to produce a much higher power output relative to what they would produce using prior art solar trackers and practices.

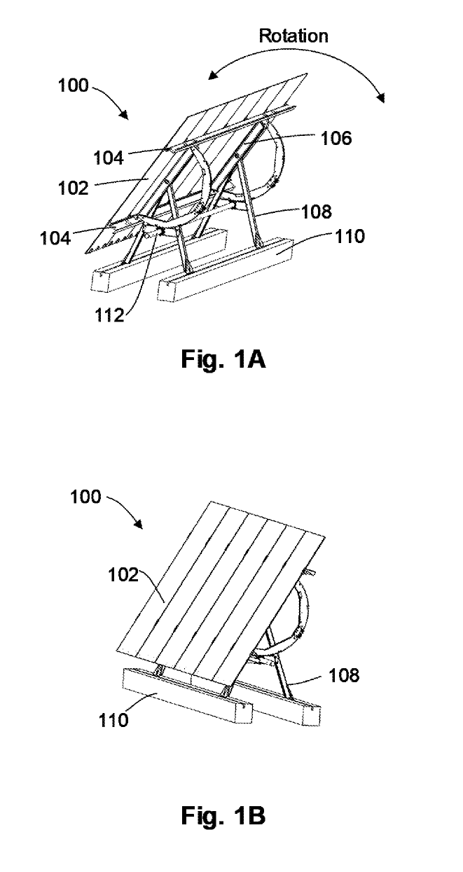

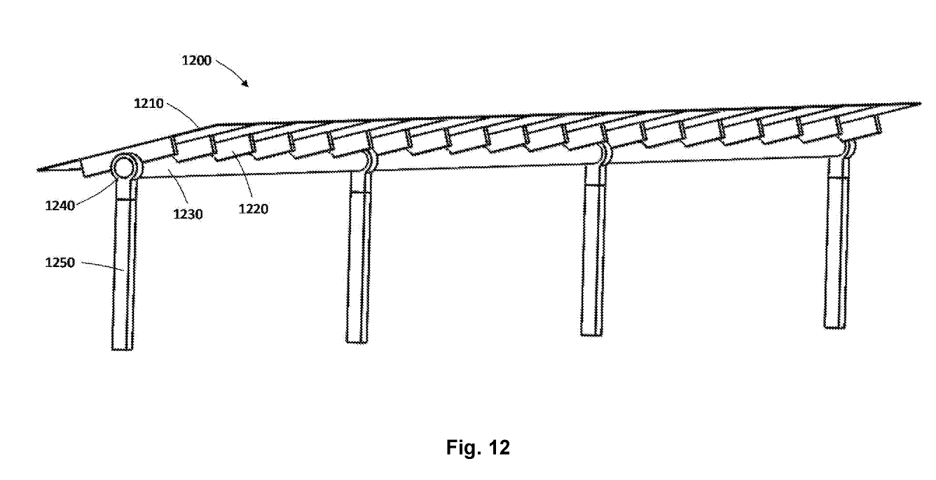

FIGS. 1A and 1B show two perspective views of a solar tracker 100 with a number of solar panels 102 mounted on it. The solar panels 102 can be supported by two purlins 104. The purlins 104 can be connected by two pivot arms 106, which are perpendicular to the purlins. The pivot arms rotate about an axle at the top of a support structure 108. The support structure can be supported by a ballast foundation 110. A drive system 112 uses power and torque from a motor (not shown) to rotate the solar panels and to keep them at the correct position. Other foundation designs such as piles driven into the ground or poured concrete can be used too. A variety of support designs can be used as well, such as single poles in a line along the tracker, as shown in FIG. 12, instead of the A-frames shown in FIGS. 1A and 1B. FIGS. 1A and 1B represent one solar tracker section that can be coupled with many other solar tracker sections to form a row of trackers. Multiple solar tracker rows can be grouped together for a solar field.

Continuing with FIGS. 1A and 1B, the solar panels 102 on the solar tracker 100 are bifacial panels and collect light from both the fronts and backs of the panels. If the solar tracker orients the panels so that their front sides are facing toward the sun, the front sides of the panels receive light from three sources. First, the front sides of the panels see the direct beam of the sun. Second, the front sides of the panels receive diffuse light that has been scattered by the atmosphere. This can be a significant fraction of the total light during cloudy weather or when there is a large amount of aerosols in the air, such as during a dust storm. A third source of light for the front sides of the panels is light reflected off the ground. This can be higher if the ground is more reflective or if the panels are oriented to have a better view of the ground, such as when the panels are aimed at the sun when it is low on the horizon.

The back sides of the panels typically receive light from three sources, diffuse light from the atmosphere, reflected light from the ground, and reflected light from the support structure. The back sides of the panels can also receive light from the direct beam of the sun if the solar tracker is oriented with the backs of the panels facing the sun. However, bifacial panels typically produce more light on the front than the back, and more energy is generally produced overall when the front side has a direct view of the sun.

The mounting structure can be designed differently for bifacial panels than for monofacial panels. A first consideration for a mounting structure for bifacial panels is that it allows as much light as possible to reach the back sides of the panels. The panels generate more electricity when more light hits them. A second consideration for a mounting structure for bifacial panels is that the structure allows the light to be distributed as evenly as possible. A panel is composed of a number of cells, for example 72 cells, and these cells are typically electrically connected in series. If one photovoltaic cell is shaded, then it will produce a low amount of current, and the cells wired in series with it will produce the same current as the shaded cell even if these others are not shaded. Therefore, shading one cell disproportionately reduces the power output of the entire panel.

A mounting structure can shade the backs of solar cells if structural members are mounted to the back of the solar panels and if they are placed very close to the panels. This can result in reducing the power contribution of the entire back of the panel even if a structural member only blocks some of the cells since the cells are commonly wired in series.

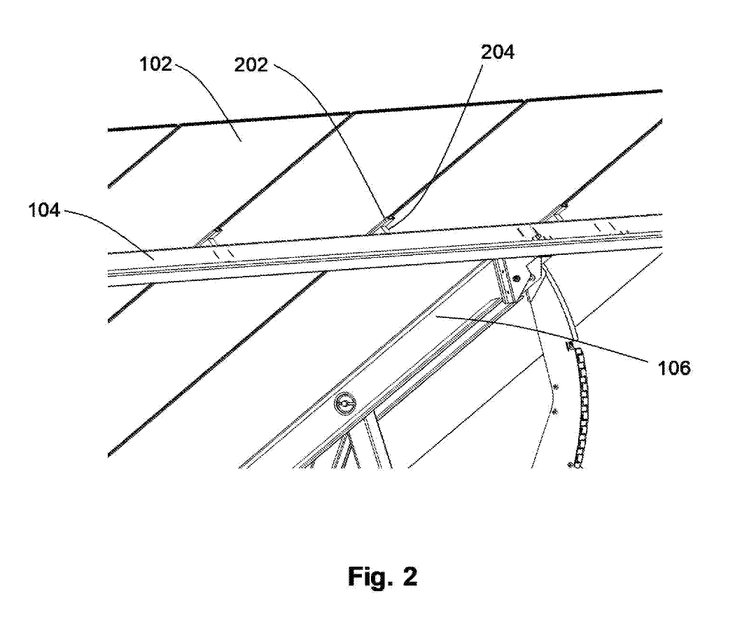

FIG. 2 schematically illustrates a detailed view of the back sides of the solar panels 102 and the mounting structure from the solar collector from FIGS. 1A and 1B. FIG. 2 shows the solar panels 102 secured to the purlins 104 by clips 202. A fastener (not shown) holds a clip securely on the solar panel and also securely to the purlin. A standoff 204 increases the gap between the solar panels 102 and the purlins 104 as well as the gap between the solar panels and the pivot arms 106. The fasteners holding the clips can pass through the standoff 204 or pass near it. The standoff 204 can be made from steel or aluminum or some other metal. An alternative embodiment is that the standoff 204 and the clip 202 can be made as one piece or one assembly as well. By increasing the gap between the solar panel 102 and purlin 104, the purlin can block much less light on the cells of the solar panels above it. The solar cells that would be shaded have a much better view of the diffuse light from the atmosphere or the light reflected off the ground.

Continuing with FIG. 2, the structural members can be treated to be highly reflective of light in the solar spectrum. This can be accomplished by painting them white, polishing them, choosing materials that are naturally more reflective, or by other means. For example, structural members can be made of galvanized steel, that when new may have a solar reflectance of 0.6 but can fall to values of 0.2 to 0.3 over time. Coating these parts white with a paint designed for solar reflectance may increase the solar reflectance to 0.85, thereby increasing the reflectance by 3× to 4× over the long term.

In one embodiment, all of the structural members are treated to be highly reflective. In another embodiment, only the purlins 104 and pivot arms 106 are treated to be highly reflective. These components are especially important because they are very close to the solar cells. Because of their proximity, they occupy a significant fraction of the view of the solar cells near them. Because the purlins 104 and pivot arms 106 partly shade the back sides of some of the cells, treating them to increase reflectivity preferentially can reflect more light onto those cells that are partly shaded. This can compensate for some shading that would otherwise cause a disproportionate drop in power output from the back sides of the panels. In another embodiment, only the tops and sides of the purlins 104 and pivot arms 106 are treated to be highly reflective because the solar cells have a good view of only these surfaces of these parts.

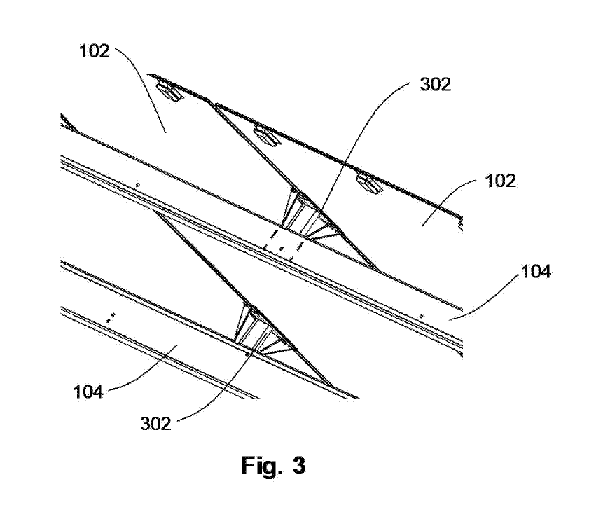

FIG. 3 schematically illustrates a close-up view of another embodiment of an attachment of solar panels to a support structure. In this embodiment, a clamp and a standoff are combined into a clamp-standoff assembly 302. The clamp-standoff assembly 302 can do three jobs: fasten the solar panel 102 to itself, fasten itself to the purlin 104, and separate the solar panels 102 from the purlins 104 with a specific gap. This gap can be on the order of a few inches. Providing such a gap can be helpful in increasing incident light on the back side of the solar panels 102, which can be increase power output of bifacial panels.

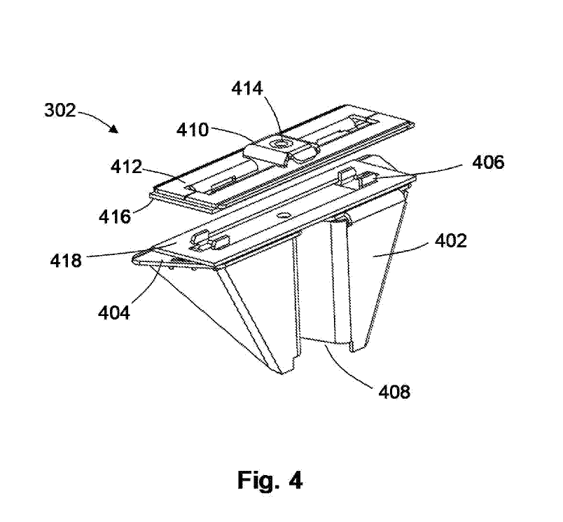

FIG. 4 schematically illustrates the clamp standoff 302 in detail. The clamp standoff 302 comprises a panel clamp system with a standoff section 402 that provides support between the purlin 104 (shown in FIGS. 2 and 3) and the solar panels 102. This panel clamp system can comprise the following components: a top bracket 412, a bottom bracket 404, a top compliant strip 416, a bottom compliant strip 418, a bolt seat 410, a fastener (not shown), and a nut (not shown). A fastener passes through a series of holes 404 in the clamp components to provide compressive force to clamp onto the solar panel 102 and also to secure the clamp system 204 to the purlin 104 or other structural member. The fastener bears onto the bolt seat 410, and the bolt seat 410 spreads out the compressive force from the fastener onto a wide area around the top bracket 412. The top bracket 412 presses downward onto the top compliant strip 416, which because it is soft, spreads out the force on the solar panel 102 to reduce the pressure. The bottom bracket 414 similarly presses upward on a bottom compliant strip 418 and on the solar panel 102. The top bracket 412 and the bottom bracket 414 each have rails 406. The rails 406 serve to locate the compliant strips 506 and 508 since the compliant strips fit around the rails. The rails 406 also serve to locate the top and bottom brackets 412 and 414 with each other. The rails 406 also serve as stops so that in assembly a worker can push the PV panel 102 up against the rail so that the worker has a reference point to properly locate the PV panel 102 before tightening the fastener and nut.

The bottom bracket 404 can be formed as a part of the same component as the standoff section 402. A fastener and nut (not shown) can be used with the series of holes 414 in the assembly to provide compression. Also in this variation, rails 406 can be used to locate the compliant strips 416 and 418 and also to serve as locating features to properly position the solar panels 102 during assembly. A cut-out 408 in the bottom of the standoff section 402 can be used to properly orient and position the clamp-standoff 302 on the purlin 104 (not shown). These features can be paired with the standoff section 402 and associated features to enable separation of the solar panel 102 from the purlins 104, as in FIG. 3.

Maintenance processes can be done on solar panels to prevent performance degradation or to increase performance. Maintenance processes could include cleaning solar panels, depositing coatings on solar panels, or performing other suitable task(s). Bifacial panels can benefit from such maintenance processes on both sides of the panels because they collect light from both sides.

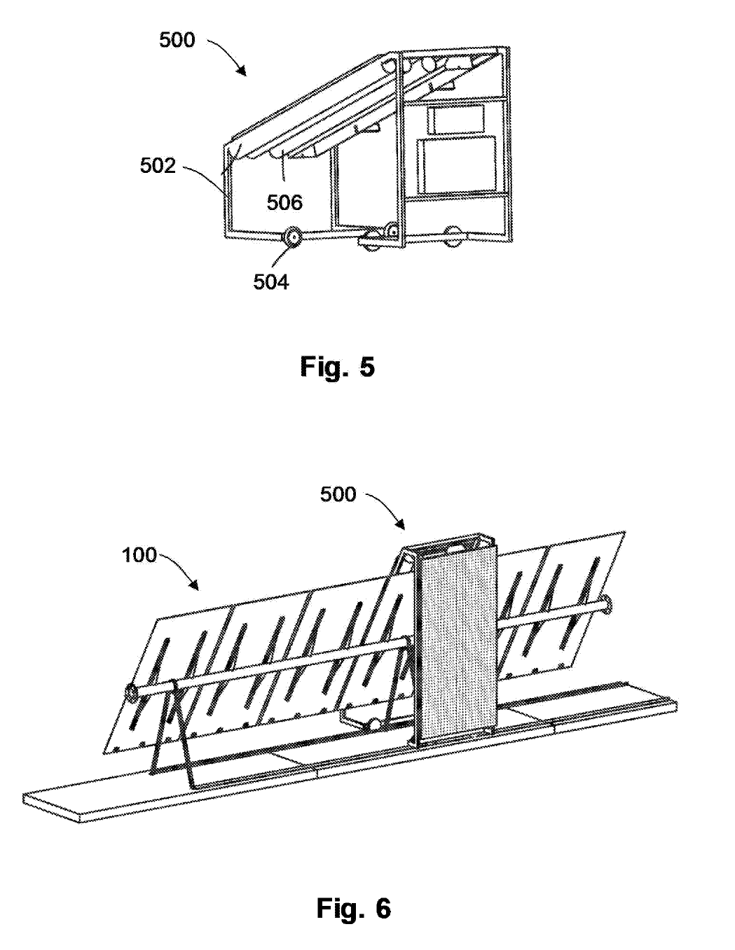

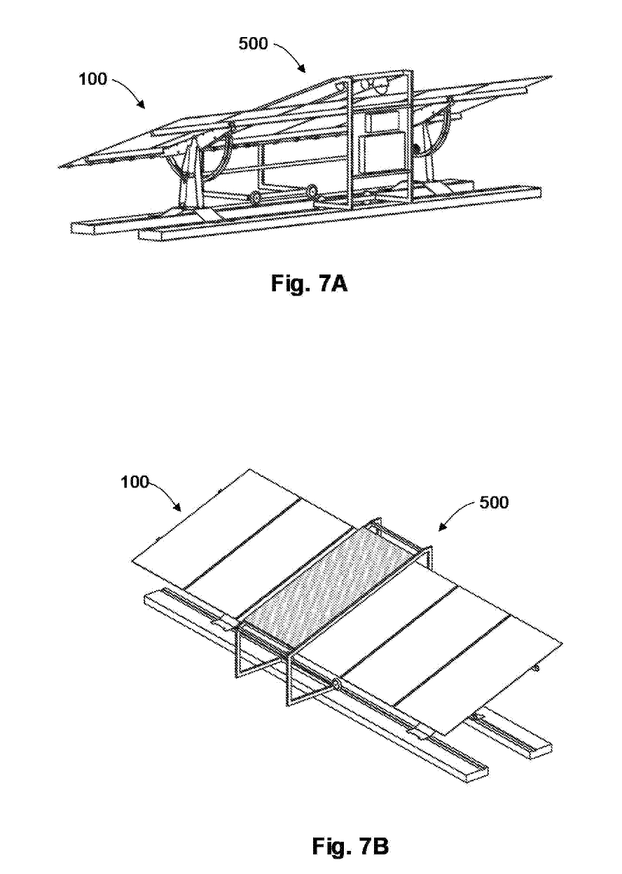

FIG. 5 schematically illustrates a perspective view of a maintenance vehicle 500 which can travel along a row of solar collectors and conduct maintenance processes as it goes. The maintenance vehicle 500 includes a frame 502, wheels 504, and maintenance implements 506. The maintenance vehicle 500 can have a variety of other components too, such as a control system, a drive system, a wireless communication system, implements for a second maintenance process, storage of consumables, an onboard pretreatment system to treat consumables before depositing them, or other components or systems. The maintenance vehicle 500 can be self-powered or can be pushed or towed by something else like by another vehicle, by a winch, or by workers. The wheels 504 can travel on the solar collector foundation 110, shown in FIGS. 1A and 1B, which can double as a track. The wheels 504 can also travel along another track or roll along on the ground. FIG. 6 shows a perspective view of a maintenance vehicle 500 performing a maintenance task on a solar collector 100. FIGS. 7A and 7B show perspective views of another embodiment of a maintenance vehicle 500 performing a maintenance task on a solar collector 100.

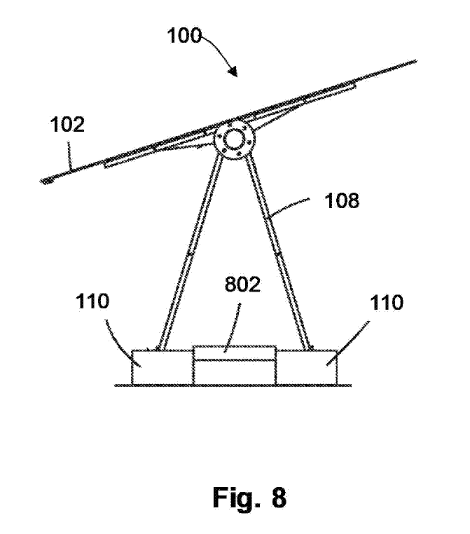

FIG. 8 schematically illustrates another embodiment of a maintenance vehicle 802 that can perform maintenance on a solar collector 100. In this case, the maintenance vehicle drives underneath the solar collector. It can travel below the support structure 108 on a ballast foundation 110 to perform tasks from below the solar panels 102.

In the embodiments of maintenance vehicles shown in FIGS. 5 through 8, the maintenance vehicles each have a particular viewpoint of the solar panels, for example being above them or being below them.

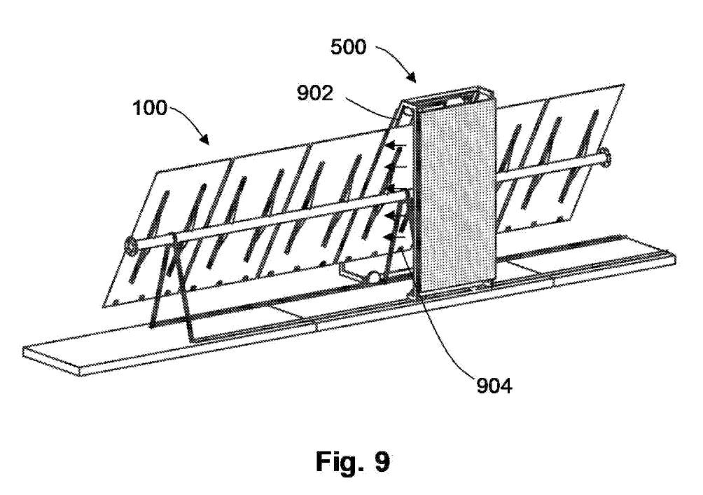

FIG. 9 schematically illustrates an alternative embodiment of a solar collector 100 that is being serviced by a cleaning machine 500. The cleaning machine 500 can clean the front sides of the panels by a combination of one or more of a water spray, brushes, and wipers 902. The cleaning machine 500 can also clean the back sides of the panels with the water spray 904 that is emitted from the other side of the cleaning machine 500. The cleaning machine 500 can be arranged to clean the panels when they are tilted, as is shown. The cleaning machine 500 can alternatively be arranged to clean the panels when they are parallel to the earth's surface, with the water spray 902 pointed upward from the bottom of the cleaning machine 500 while the brushes, wipers, and water spray 902 point downward from the cleaning machine 500 onto the fronts of the panels, which are pointed upward.

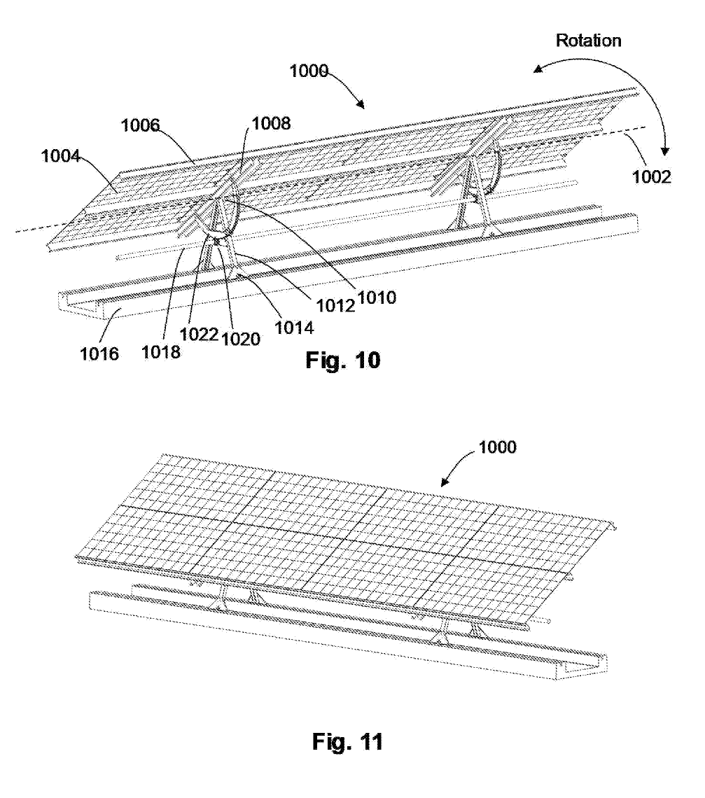

A perspective view of a tracking solar collector 1000 is shown in FIG. 10, and a second perspective view of the same solar collector is shown in FIG. 11, according to some embodiments. One of ordinary skill in the art would recognize many variations, alternatives, and modifications. The solar collector 1000 can track the sun about one tracking axis 1002, which is parallel to the ground. The solar collector 1000 includes PV panels 1004, a structure, and a foundation 1016. For example, the PV panels 1004 are rectangular in shape. In the solar collector 1000, the PV panels 1004 are positioned with their long ends parallel to the tracking axis 1002 and with two or more panels 1004 besides one another, transverse to the tracking axis 1002. FIGS. 10 and 11 feature embodiments with two panels across, but three or more panels can be arranged in the same manner. The PV panels 1004 can be fastened along their long edges with clips to purlins 1006 that are aligned parallel to the tracking axis 1002. Three purlins 1006 are shown, and more purlins can be added if more than two PV panels were arranged transverse to the tracking axis 1002.

In another example, some PV panels 1004, known as bifacial PV panels 1004, can receive light from both the front and back sides, and the structural members in this solar collector 1000 are positioned so that they do not block light from hitting the back sides of the bifacial PV panels 1004. The purlins 1006, pivot arms 1008, and/or other structural can be treated to be reflective so that additional light can be reflected onto the back sides of bifacial PV panels 1004. These structural elements can be made reflective by painting them white, by coating them with a reflective coating, by polishing them, by choosing materials that are naturally reflective, or by treating them by other means.

In one embodiment, continuing with FIG. 10, the purlins 1006 are fastened to two pivot arms 1008. Each pivot arm 1008 is attached at a pivot point 1010 to two sets of legs 1012. The pivot points 1010 are used to determine the tracking axis 1002. Feet 1014 are located at the bottoms of the legs and attach the legs to the concrete foundation 1016. The concrete foundation 1016 is shown in FIG. 10 as one piece, but two or four pieces could be used as ballast for the solar collector 1000. For example, the concrete could be formed by slip-forming, by casting it in place, or by using pre-cast blocks. In another example, the feet 1014 can be located in grooves in the concrete and fastened with an adhesive.

In another embodiment, continuing with FIG. 10, tracking action is driven by a motor and gearing system that is connected to the drive shaft 1018, which can be a hollow drive tube. The motor and gearing system rotates the drive shaft, and the drive shaft 1018 uses a pinion gear 1020 to rotate an arc gear 1022, which is fixed to the pivot arm 1008. For example, one pinion-gear/arc-gear system is used per leg set 1012. In another example, one pinion-gear/arc-gear system is used per solar collector.

Similar to the solar collector in FIG. 1, the concrete ballast 1016 of the solar collector in FIG. 10 can serve as a track for a driving vehicle. In another example, such a vehicle can be used for transporting people and equipment, performing maintenance tasks such as cleaning, performing diagnostics, and/or making measurements.

FIG. 12 shows a perspective view of a tracking solar collector 1200 with a number of bifacial solar panels 1210 mounted on it. The bifacial solar panels 1210 can be supported by a support structure comprising standoffs 1220, a torque tube 1230, a bearing 1240, and posts 1250. The torque tube 1230 forms an axis about which the solar panels 1210 are rotated. The torque tube 1230 and/or standoffs 1220 are fashioned to be reflective to reflect additional light to the back side of the bifacial solar panels 1210, such as by painting them white, by coating them with a reflective coating, by polishing them, by choosing materials that are naturally reflective, or by treating them by other means.

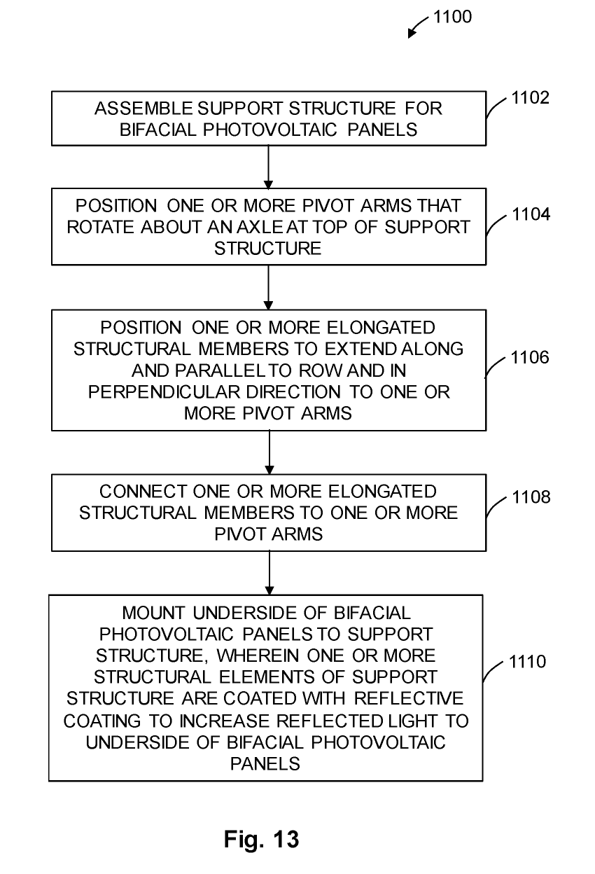

FIG. 13 depicts a flow diagram 1300 for assembling a system for rotating bifacial photovoltaic panels arranged in a row. At 1302, a support structure is assembled for the bifacial photovoltaic panels. One or more pivot arms that rotate about an axle at a top of the support structure are positioned at 1304. At 1306, one or more elongated structural members are positioned to extend along and parallel to the row and in a perpendicular direction to the one or more pivot arms. The one or more elongated structural members are connected to the one or more pivot arms at 1308. At 1310, an underside of the bifacial photovoltaic panels is mounted to the support structure. One or more structural elements of the support structure are coated with a reflective coating to increase reflected light to the underside of the bifacial photovoltaic panels.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it is used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” In addition, use of the term “based on,” above and in the claims is intended to mean, “based at least in part on,” such that an unrecited feature or element is also permissible.

The subject matter described herein can be embodied in systems, apparatus, methods, and/or articles depending on the desired configuration. The implementations set forth in the foregoing description do not represent all implementations consistent with the subject matter described herein. Instead, they are merely some examples consistent with aspects related to the described subject matter. Although a few variations have been described in detail above, other modifications or additions are possible. In particular, further features and/or variations can be provided in addition to those set forth herein. For example, the implementations described above can be directed to various combinations and subcombinations of the disclosed features and/or combinations and subcombinations of several further features disclosed above. In addition, the logic flows depicted in the accompanying figures and/or described herein do not necessarily require the particular order shown, or sequential order, to achieve desirable results. Other implementations may be within the scope of the following claims.

What is claimed is:

1. A system comprising:
a support structure configured to be mounted to an underside of bifacial photovoltaic panels arranged in a row, the support structure comprising:
one or more elongated structural members extending along and in a direction parallel to the row; and
one or more pivot arms that rotate about an axle at a top of the support structure, the one or more pivot arms positioned in a perpendicular direction to the one or more elongated structural members, the one or more pivot arms connected to the one or more elongated structural members,
wherein one or more structural elements of the support structure have a reflective outer surface to increase reflected light to the underside of the bifacial photovoltaic panels.

2. The system of claim 1, further comprising:
a standoff positioned between the bifacial photovoltaic panels and the one or more elongated structural members to spatially offset the bifacial photovoltaic panels from the one or more elongated structural members and the one or more pivot arms, the standoff connecting the bifacial photovoltaic panels to the one or more elongated structural members, the standoff reducing an amount of obstruction to the underside of the bifacial photovoltaic panels and increasing an amount of light that reaches the underside of the bifacial photovoltaic panels.

3. The system of claim 1, wherein the one or more structural elements are painted white.

4. The system of claim 1, wherein the one or more structural elements are polished to make the one or more structural elements reflective.

5. The system of claim 1, wherein the support structure is treated to have a reflectivity above a pre-defined threshold.

6. The system of claim 1, wherein the one or more elongated structural members are treated to be have a reflectivity above a pre-defined threshold.

7. The system of claim 2, wherein the support structure further comprises:
one or more clips securing the bifacial photovoltaic panels to the one or more elongated structural members.

8. The system of claim 7, wherein the support structure further comprises:
one or more fasteners that secure the one or more clips to the bifacial photovoltaic panels and the one or more elongated structural members.

9. The system of claim 8, wherein the one or more fasteners pass through the standoff.

10. A method for assembling a system for rotating bifacial photovoltaic panels arranged in a row, the method comprising:
assembling a support structure for the bifacial photovoltaic panels, assembling the support structure comprising:
positioning one or more pivot arms that rotate about an axle at a top of the support structure;
positioning one or more elongated structural members to extend along and parallel to the row and in a perpendicular direction to the one or more pivot arms; and
connecting the one or more elongated structural members to the one or more pivot arms; and
mounting an underside of the bifacial photovoltaic panels to the support structure,
wherein one or more structural elements of the support structure are coated with a reflective coating to increase reflected light to the underside of the bifacial photovoltaic panels.

11. The method of claim 10, further comprising:
positioning a standoff between the bifacial photovoltaic panels and the one or more elongated structural members to spatially offset the bifacial photovoltaic panels from the one or more elongated structural members and the one or more pivot arms, the standoff connecting the bifacial photovoltaic panels to the one or more elongated structural members, the standoff reducing an amount of obstruction to the underside of the bifacial photovoltaic panels and increasing an amount of light that reaches the underside of the bifacial photovoltaic panels.

12. The method of claim 10, wherein the one or more structural elements are painted white.

13. The method of claim 10, wherein the one or more structural elements are polished to make the one or more structural elements reflective.

14. The method of claim 10, wherein the support structure is coated to have a reflectivity above a certain threshold.

15. The method of claim 10, wherein the one or more elongated structural members are coated to be have a reflectivity above a certain threshold.

16. The method of claim 11, wherein the support structure further comprises:
one or more clips securing the bifacial photovoltaic panels to the one or more elongated structural members.

17. The method of claim 16, wherein the support structure further comprises:
one or more fasteners that secure the one or more clips to the bifacial photovoltaic panels and the one or more elongated structural members.

18. The method of claim 17, wherein the one or more fasteners pass through the standoff.

19. A system comprising:
a support structure comprising:
one or more elongated structural members extending along and parallel to the row; and
one or more pivot arms that rotate about an axle at a top of the support structure positioned in a perpendicular direction to the one or more elongated structural members, the one or more pivot arms connected to the one or more elongated structural members;
one or more bifacial photovoltaic panels arranged in a row, the one or more bifacial photovoltaic panels affixed to the support structure,
wherein the one or more elongated structural members have an outer surface with a reflective coating to increase reflected light to the surface of the one or more bifacial photovoltaic panels.

20. The system of claim 19, wherein the one or more elongated structural members are painted white or polished to make the elongated structural members reflective.
